(19) United States
(12) Patent Application Publication
(10) Pub. No.: US 2026/0040880 A1
(43) Pub. Date: Feb. 5, 2026

(54) DEPOSITION DEVICE, ELECTRONIC DEVICE AND METHOD OF DEPOSITION FOR DISPLAY DEVICE

(71) Applicants: Samsung Display Co., LTD., Yongin-si (KR); ULVAC, INC., Kanagawa (JP)

(72) Inventors: Kyung Hoon CHUNG, Yongin-si (KR); Shinjiro KURAHASHI, Kanagawa (JP); Masao NISHIGUCHI, Kanagawa (JP); Daisuke IWASE, Kanagawa (JP); Jung Seob LEE, Yongin-si (KR); Yong Sic JEON, Yongin-si (KR); Hyeon Sik KIM, Yongin-si (KR); Yong YEO, Yongin-si (KR)

(21) Appl. No.: 19/210,234

(22) Filed: May 16, 2025

(30) Foreign Application Priority Data
Jul. 31, 2024 (KR) 10-2024-0101616

(51) Int. Cl. H01L 21/68; C23C 14/04; C23C 14/50; H01L 21/677; H10K 59/12; H10K 71/16

(52) U.S. Cl. CPC H01L 21/682; C23C 14/042; C23C 14/50; H01L 21/67709; H10K 59/1201; H10K 71/166

(57) ABSTRACT

A deposition device for a display device includes: a chamber, a deposition source in the chamber, a stage on the deposition source; a mask structure on the stage; a substrate tray on the mask structure; a magnet plate on the substrate tray; a transport track passing through a first gate of the chamber and a second gate of the chamber and disposed inside the chamber and outside the chamber, a first carrier transporting the mask structure along the transport track; and a second carrier transporting the substrate tray along the transport track.

This application claims priority to Korean Patent Application No. 10-2024-0101616, filed on Jul. 31, 2024, and all the benefits accruing therefrom under 35 U.S.C. § 119, the content of which in its entirety is herein incorporated by reference.

### BACKGROUND

### 1. Field

An embodiment relates to a deposition deice for a display device, and more particularly, to a deposition device, an electronic device and method of a deposition for a display device which may minimize manufacturing cost, tact time, and misalignment.

### 2. Description of the Related Art

Organic light-emitting diode displays have self-luminous characteristics and, unlike liquid crystal displays, a separate light source is not desired and thus organic light-emitting diode displays may be reduced in thickness and weight compared to the liquid crystal displays. In addition, organic light-emitting diode displays are attracting attention as next-generation displays for portable electronic devices due to their high-quality characteristics such as relatively low power consumption, relatively high luminance, and relatively high response speed.

### SUMMARY

Features of the disclosure provide a deposition device, an electronic device and method of a deposition for a display device which may minimize manufacturing cost, tact time, and misalignment.

According to a feature of the disclosure, there is provided a deposition device for a display device. The deposition device includes: a chamber; a deposition source in the chamber; a stage on the deposition source; a mask structure on the stage; a substrate tray on the mask structure; a magnet plate on the substrate tray; a transport track passing through a first gate of the chamber and a second gate of the chamber and disposed inside the chamber and outside the chamber; a first carrier transporting the mask structure along the transport track; and a second carrier transporting the substrate tray along the transport track.

According to another feature of the disclosure, there is provided a method of a deposition for a display device. The deposition method includes: placing a deposition source, a stage, a first driving mechanism, a magnet plate attached to the first driving mechanism, a second driving mechanism, a pusher, and a transport track between a first inner wall of a chamber and a second inner wall of the chamber; loading a first carrier loaded with a mask structure, which includes a mask, into the chamber by moving the first carrier along the transport track; attaching the second driving mechanism and the mask structure in the first carrier to each other; releasing a constraining force of support members of the first carrier applied to the mask structure by lowering the first carrier and the support members of the first carrier by pressing the first carrier with the pusher; separating the mask structure from the first carrier by moving the second driving mechanism to which the mask structure is attached; placing the mask structure on the stage by moving the second driving mechanism toward the stage; separating the second driving mechanism and the mask structure; placing the second driving mechanism between the transport track and the second inner wall of the chamber; moving the pusher to an original position; unloading the first carrier from the chamber by moving the first carrier along the transport track; loading a second carrier loaded with a substrate tray, which includes a substrate, into the chamber by moving the second carrier along the transport track; attaching the second driving mechanism and the substrate tray in the second carrier to each other; releasing a constraining force of support members of the second carrier applied to the substrate tray by lowering the second carrier and the support members of the second carrier by pressing the second carrier with the pusher; separating the substrate tray from the second carrier by moving the second driving mechanism to which the substrate tray is attached; placing the substrate tray on the mask structure by moving the second driving mechanism toward the mask structure on the stage; placing the magnet plate on the substrate tray by moving the first driving mechanism toward the substrate tray; and depositing a deposition material from the deposition source on the substrate through the mask of the mask structure.

According to a feature of the disclosure, there is provided an electronic device. The electronic device includes: a display device, wherein a deposition device for depositing a deposition material to a substrate of the display device includes a chamber; a deposition source in the chamber; a stage on the deposition source; a mask structure on the stage; a substrate tray on the mask structure; a magnet plate on the substrate tray; a transport track passing through a first gate of the chamber and a second gate of the chamber and disposed inside the chamber and outside the chamber; a first carrier transporting the mask structure along the transport track; and a second carrier transporting the substrate tray along the transport track.

However, the effects of the disclosure are not restricted to the one set forth herein. The above and other effects of the disclosure will become more apparent to one of daily skill in the art to which the disclosure pertains by referencing the claims.

### BRIEF DESCRIPTION OF THE DRAWINGS

These and/or other features will become apparent and more readily appreciated from the following description of the embodiments, taken in conjunction with the accompanying drawings in which:

FIG. 1 is a schematic diagram of an embodiment of a deposition device;

FIG. 2 is a perspective view of a mask structure of FIG. 1;

FIG. 3 is a perspective view of a stage and a frame of FIG. 1;

FIG. 4 is a perspective view of a first carrier disposed on a transport track;

FIG. 5 is an enlarged view of area A1 of FIG. 4;

FIG. 6 is a view for explaining the coupling of the mask structure to the first carrier of FIG. 4;

FIG. 7 is an enlarged view of area A2 of FIG. 6;

FIGS. 8 and 9 are views for explaining the separation of the first carrier from the mask structure;

FIG. 10 is a perspective view of a substrate tray of FIG. 1;

FIG. 11 is a view for explaining the coupling of the substrate tray of FIG. 10 to a second carrier; and

FIGS. 12, 13, and 14 are views for explaining an embodiment of a deposition method of the deposition device.

FIG. 15 is a block diagram of an embodiment of an electronic device.

FIGS. 16, 17, and 18 are schematic diagrams of electronic devices according to various embodiments.

### DETAILED DESCRIPTION

Embodiments of the disclosure will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when a layer is referred to as being “on” another layer or substrate, it may be directly on the other layer or substrate, or intervening layers may also be present. The same reference numbers indicate the same components throughout the specification. In the attached drawing figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the disclosure may be combined partially or totally. As will be clearly appreciated by those skilled in the art, technically various interactions and operations are possible. Various embodiments may be practiced individually or in combination.

Hereinafter, embodiments will be described in detail with reference to the accompanying drawings.

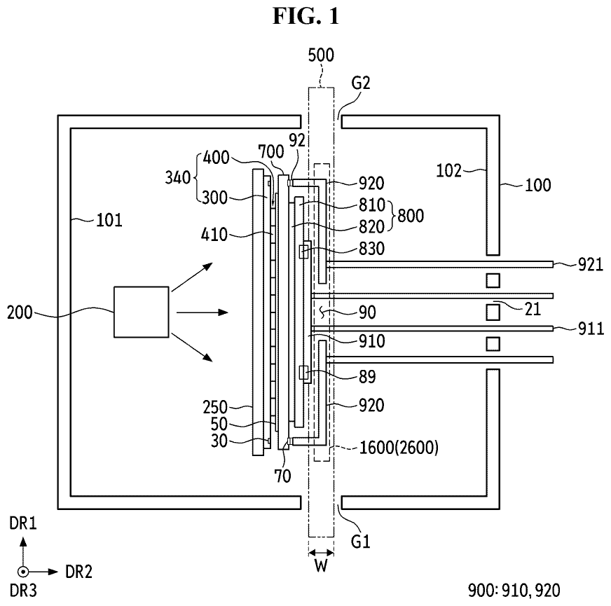

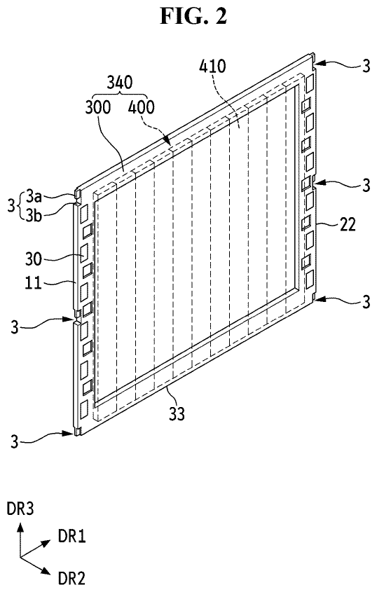

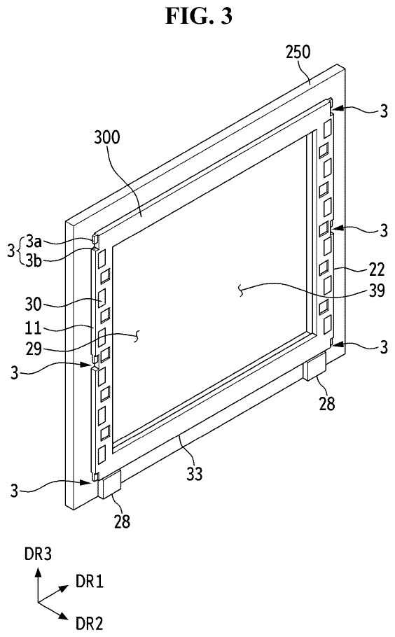

FIG. 1 is a schematic diagram of an embodiment of a deposition device. FIG. 2 is a perspective view of a mask structure 340 of FIG. 1. FIG. 3 is a perspective view of a stage 250 and a frame 300 of FIG. 1. In FIGS. 1 through 3, a reverse direction (hereinafter, also referred to as a third reverse direction) of a third direction DR3 may be the direction of gravity.

The deposition device for a display device in the embodiment may include a chamber 100, a deposition source 200, the stage 250, the mask structure 340, a substrate tray 700, a magnet plate 800, a transport track 500, a first carrier 1600, and a driving mechanism 900 as illustrated in FIG. 1.

The chamber 100 may define a deposition space in which a deposition process is performed. A layer deposition process for manufacturing an organic light-emitting diode display device may be performed inside the chamber 100. The chamber 100 may be a vacuum chamber 100. The deposition source 200, the stage 250, the driving mechanism 900, and a portion of the transport track 500 described above may be disposed inside the chamber 100. When a deposition process is in progress, the deposition source 200, the stage 250, the mask structure 340, a substrate 50, the substrate tray 700, the magnet plate 800, a portion of the transport track 500, and the driving mechanism 900 may be disposed inside the chamber 100.

The deposition source 200 may be disposed inside the chamber 100. In an embodiment, the deposition source 200 may be disposed between a first inner wall 101 of the chamber 100 and the stage 250, for example. The deposition source 200 may provide a deposition material. The deposition material from the deposition source 200 may pass through an opening 29 of the stage 250 and move toward the mask structure 340. Specifically, the deposition source 200 may evaporate a deposition material such as an organic material or an electrode material by heating the deposition material to a relatively high temperature, and the evaporated deposition material may be deposited on the substrate 50 through pattern holes of the mask structure 340. The organic material may be a material for manufacturing a hole injection layer, a hole transport layer, a light-emitting layer, an electron transport layer, and an electron injection layer disposed between an anode and a cathode of an organic light-emitting diode, for example. The substrate 50 may be a substrate used in a display device including organic light-emitting diodes, for example.

The stage 250 may be disposed on the deposition source 200. In an embodiment, the stage 250 may be disposed between the deposition source 200 and the mask structure 340, for example. The stage 250 may be disposed in a fixed state inside the chamber 100. The stage 250 may be tilted toward the deposition source 200. In an embodiment, the stage 250 may be tilted in a reverse direction (hereinafter, also referred to as a second reverse direction) of a second direction DR2 with respect to the third direction DR3, for example. Accordingly, an angle defined between a surface of the stage 250 which faces the deposition source 200 and the ground (e.g., a bottom surface of the chamber 100) on which the stage 250 is disposed may be an acute angle. Here, as illustrated in FIG. 3, supports 28 may be disposed on a lower side of the stage 250 to protrude from a surface of the lower side along the second direction DR2. The stage 250 may be shaped like a quadrangular frame with a penetrated central portion. In an embodiment, the stage 250 may define the opening 29 in the central portion, for example. The stage 250 may further include electro-permanent magnets. In an embodiment, the electro-permanent magnets may be disposed on a surface of the stage 250 which faces the mask structure 340, for example.

The mask structure 340 may be disposed on the stage 250. In an embodiment, the mask structure 340 may be disposed between the stage 250 and the substrate tray 700, for example. The mask structure 340 may be disposed on the supports 28 of the stage 250. Here, since the stage 250 is tilted, the mask structure 340 may also be tilted on the stage 250. The mask structure 340 may include the frame 300 and a mask 400.

The frame 300 may be disposed on the stage 250. In an embodiment, the frame 300 may be disposed between the stage 250 and the mask 400, for example. The frame 300 may be shaped like a quadrangular frame with a penetrated central portion. In an embodiment, the frame 300 may define an opening 39 in the central portion, for example. Grooves 30 may be defined at both edges of the frame 300. The frame 300 may include a magnetic material. In an embodiment, the frame 300 may include a material (e.g., iron (Fc)) that may be attracted to a magnet, for example.

As illustrated in FIG. 3, at least one detachable member 3 may be disposed at the edges of the frame 300. In an embodiment, a detachable member 3 may be disposed near each corner of the quadrangular frame 300, for example. Specifically, the frame 300 may have six detachable members 3. Here, three of the six detachable members 3 may be disposed at the top, middle and bottom of a first side 11 of the frame 300, respectively, and the remaining three detachable members 3 may be disposed at the top, middle and bottom of a second side 22 of the frame 300, respectively. The first side 11 and the second side 22 of the frame 300 may face each other along a first direction DR1.

Each detachable member 3 may include a coupling tip 3a, and a separation groove 3b may be defined next (adjacent) to the coupling tip 3a in each detachable member 3 in the third direction DR3. The coupling tip 3a may be disposed higher than the separation groove 3b. In an embodiment, in one detachable member 3, the coupling tip 3a may be disposed higher than the separation groove 3b in the third direction DR3, for example. The coupling tip 3a may have a smaller thickness (e.g., size in the second direction DR2) than other parts of the frame 300. The separation groove 3b may be recessed from the first side 11 of the frame 300 toward the second side 22 or may be recessed from the second side 22 toward the first side 11. In an embodiment, separation grooves 3b defined in different sides and facing each other may be recessed toward each other, for example.

The mask 400 may be disposed on the frame 300. In an embodiment, the mask 400 may be disposed between the frame 300 and the substrate tray 700, for example. The mask 400 may be disposed on the frame 300 to cover the opening 39 of the frame 300. Edges of the mask 400 may be attached to the frame 300. In an embodiment, the mask 400 may be attached to the frame 300 by welding, for example. The mask 400 may be a fine metal mask (“FMM”).

The mask 400 may include a plurality of sub-masks 410 (or mask sticks). Each of the sub-masks 410 may have a quadrangular shape, e.g., rectangular shape extending in the third direction DR3. The sub-masks 410 may be arranged along the first direction DR1. Next (adjacent) sub-masks 410 may contact each other. Each sub-mask 410 excluding both edges may be disposed on the opening 39 of the frame 300. Although not illustrated, each sub-mask 410 may have a plurality of pattern holes penetrating the sub-mask 410 in the second direction DR2. A deposition material from the deposition source 200 may be deposited on the substrate 50 through the pattern holes of each sub-mask 410. Each sub-mask 410 may include or consist of a material including a magnetic material (e.g., iron (Fe)). In an embodiment, each sub-mask 410 may include a material that is attracted to a magnet, for example.

The substrate tray 700 may be disposed on the mask structure 340. In an embodiment, the substrate tray 700 may be disposed between the mask 400 of the mask structure 340 and the magnet plate 800, for example. The substrate tray 700 may transport the substrate 50. Here, the substrate tray 700 may adsorb the substrate 50 using an electrostatic force. In an embodiment, the substrate tray 700 may provide a surface on which the substrate 50 is placed while serving as an electrostatic chuck which adsorbs and fixes the substrate 50 to the surface of the substrate tray 700, for example. The substrate tray 700 may include or consist of a material including ceramic or titanium.

The magnet plate 800 may be disposed on the substrate tray 700. In an embodiment, the magnet plate 800 may be disposed between the substrate tray 700 and the driving mechanism 900, for example. The magnet plate 800 may be disposed on the substrate tray 700 to face the substrate tray 700. The magnet plate 800 may provide a magnetic force. In an embodiment, the magnet plate 800 may provide a magnetic force so that the metal mask 400 described above is closely attached to the substrate 50, for example.

The magnet plate 800 may include a base member 810 and a plurality of magnets 820 disposed on the base member 810. In an embodiment, the magnets 820 may be disposed on the base member 810, for example. As a predetermined example, when a side surface of the base member 810 which faces the substrate tray 700 is defined as a first surface, the magnets 820 may be disposed on the first surface of the base member 810. Each magnet 820 may include, e.g., a permanent magnet.

Each of the magnets 820 may have an N pole and an S pole. A plurality of magnets 820 disposed along the first direction DR1 may be disposed such that opposite polarities face each other in the first direction DR1. A plurality of magnets 820 disposed along the second direction DR2 may be disposed such that opposite polarities face each other.

When a surface opposite the first surface of the base member 810 is defined as a second surface of the base member 810, a plurality of magnetic objects 830 may be disposed on the second surface of the base member 810. In an embodiment, the magnetic objects 830 may be disposed on the second surface in coupling grooves of the base member 810, for example. In an embodiment, the magnetic objects 830 may include a material (e.g., iron (Fe)) that may be attracted to a magnet, for example.

The driving mechanism 900 may include a first driving mechanism 910 and a second driving mechanism 920.

The first driving mechanism 910 may be disposed between the magnet plate 800 and the second driving mechanism 920. In an embodiment, the first driving mechanism 910 may be disposed between the base member 810 of the magnet plate 800 and the second driving mechanism 920, for example. The first driving mechanism 910 may include magnets 89. In an embodiment, the magnets 89 may be disposed on a surface opposite a surface of the first driving mechanism 910 which is connected to a first driving shaft 911, for example. The magnets 89 of the first driving mechanism 910 may correspond to (or overlap) the magnetic objects 830 of the magnet plate 800. The magnets 89 may include permanent magnets.

The magnet plate 800 may be detachably attached to the first driving mechanism 910. In an embodiment, the base member 810 of the magnet plate 800 may be detachably attached to the magnets 89 of the first driving mechanism 910, for example. In other words, the magnetic objects 830 of the base member 810 may be attached to the magnets 89 of the first driving mechanism 910 by a magnetic force from the magnets 89 of the first driving mechanism 910. The first driving mechanism 910 may move toward the deposition source 200 or in the opposite direction within the chamber 100. In an embodiment, the first driving mechanism 910 may move along the second reverse direction or the second direction DR2, for example. To this end, in an embodiment, the first driving mechanism 910 may be connected to the first driving shaft 911 which is extended along the second reverse direction or retracted along the second direction DR2. The first driving shaft 911 may be connected to an external driver through a hole 90 of the second driving mechanism 920 and a hole 21 of the chamber 100. In addition, the first driving mechanism 910 may move further in the first direction DR1, a first reverse direction, the third direction DR3, or the third reverse direction. In this case, the first driving shaft 911 may move further in the first direction DR1, the first reverse direction, the third direction DR3, or the third reverse direction. The movement of the magnet plate 800 attached to the first driving mechanism 910 may be controlled by the movement of the first driving mechanism 910.

The second driving mechanism 920 may be disposed between the first driving mechanism 910 and a second inner wall 102 of the chamber 100. The second driving mechanism 920 may include electro-permanent magnets 92. The substrate tray 700 may be attached to the second driving mechanism 920. In an embodiment, the substrate tray 700 may be attached to the second driving mechanism 920 as magnetic objects 70 of the substrate tray 700 are attached to the electro-permanent magnets 92 of the second driving mechanism 920, for example. The electro-permanent magnets 92 may be disposed at both edges of the second driving mechanism 920. The magnetic objects 70 may be disposed at both edges of the substrate tray 700 to correspond to the electro-permanent magnets 92. The magnetic objects 70 may include a magnetic material that is attracted to a magnet, such as iron (Fe).

The second driving mechanism 920 may also include electromagnets instead of the electro-permanent magnets 92. The second driving mechanism 920 may move toward the deposition source 200 or in the opposite direction within the chamber 100. In an embodiment, the second driving mechanism 920 may move along the second reverse direction or the second direction DR2, for example. To this end, in an embodiment, the second driving mechanism 920 may be connected to a second driving shaft 921 which is extended along the second reverse direction or retracted along the second direction DR2. In addition, the second driving mechanism 920 may move further in the first direction DR1, the first reverse direction, the third direction DR3, or the third reverse direction. In this case, the second driving shaft 921 may move further in the first direction DR1, the first reverse direction, the third direction DR3, or the third reverse direction. The movement of the substrate tray 700 attached to the second driving mechanism 920 may be controlled by the movement of the second driving mechanism 920. The second driving mechanism 920 may perform an alignment operation between the substrate 50 of the substrate tray 700 and the mask structure 340 by controlling the position of the substrate tray 700 attached to the second driving mechanism 920.

The transport track 500 may be disposed inside the chamber 100 and outside the chamber 100 to pass through a first gate G1 and a second gate G2 of the chamber 100. The transport track 500 may extend along the first direction DR1, for example. The first gate G1 and the second gate G2 may face each other.

The first carrier 1600 may move along the transport track 500. In an embodiment, the first carrier 1600 may move along the transport track 500 in a magnetic levitation manner, for example. The first carrier 1600 may transport the mask structure 340.

As described above, an upper side of the stage 250 may be tilted toward the deposition source 200. Accordingly, the mask structure 340, the substrate tray 700, the substrate 50, the magnet plate 800, the first driving mechanism 910, the second driving mechanism 920, the transport track 500, and the carrier 1600 or 2600 described above may also be tilted at the same angle as the stage 250. Accordingly, particles generated during a deposition process on the substrate 50 may fall in the direction of gravity without sticking to the substrate 50. Therefore, the substrate 50 may be prevented from being contaminated by the particles.

In an embodiment, the transport track 500 may have a width W which will be further described in detail below.

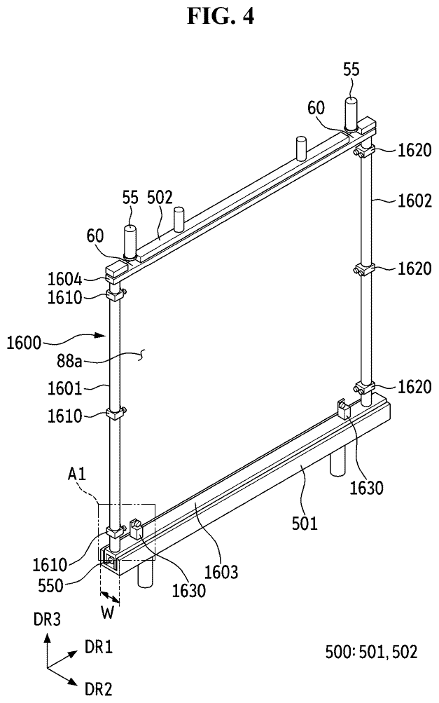

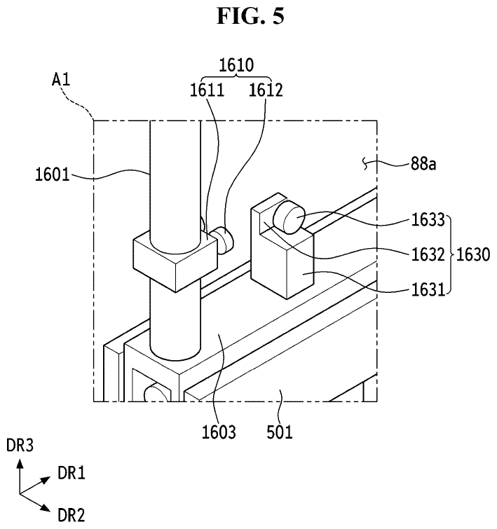

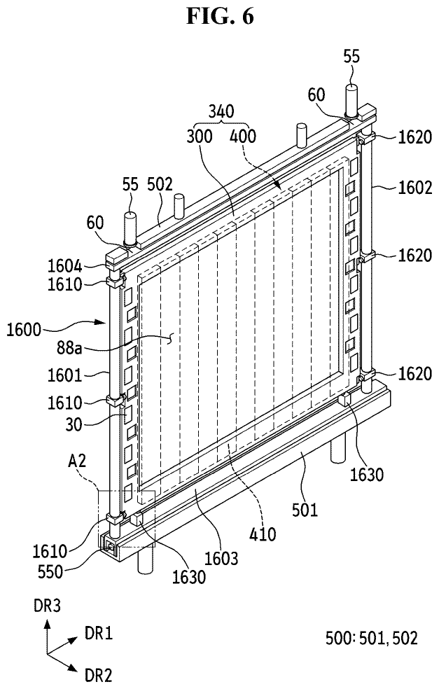

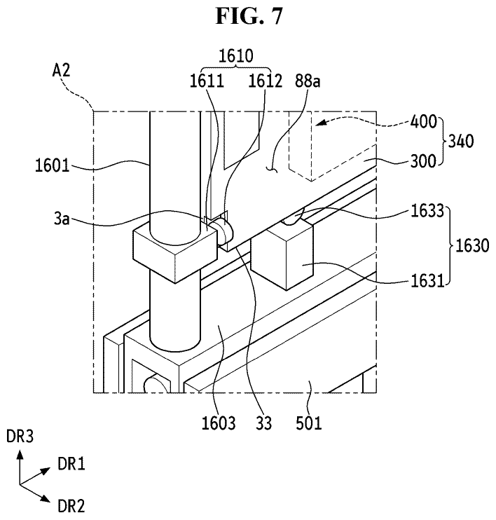

FIG. 4 is a perspective view of the first carrier 1600 disposed on the transport track 500. FIG. 5 is an enlarged view of area A1 of FIG. 4. FIG. 6 is a view for explaining the coupling of the mask structure 340 to the first carrier 1600 of FIG. 4. FIG. 7 is an enlarged view of area A2 of FIG. 6. Here, FIG. 4 may be a perspective view of the first carrier 1600 disposed on the transport track 500 of FIG. 1.

The first carrier 1600 may move along the transport track 500. The transport track 500 may include a lower track 501 and an upper track 502 facing each other in the third direction DR3. The lower track 501 may have a U-shaped cross section, and the upper track 502 may have a bar shape. The first carrier 1600 may be disposed between the lower track 501 and the upper track 502. The first carrier 1600 may move along the transport track 500 between the lower track 501 and the upper track 502.

The first carrier 1600 may be shaped like a quadrangular frame as in the example illustrated in FIG. 4. However, the shape of the first carrier 1600 is not limited thereto and may be changed to various shapes.

The first carrier 1600 may include a plurality of bars 1601, 1602, 1603 and 1604 and a plurality of support members 1610, 1620 and 1630. In an embodiment, the first carrier 1600 may include a first bar 1601, a second bar 1602, a third bar 1603, and a fourth bar 1604 connected to each other, for example. The mask structure 340 may be placed in an area (e.g., an opening 88a) surrounded and defined by the first bar 1601, the second bar 1602, the third bar 1603, and the fourth bar 1604. Here, the third bar 1603 may have a U-shaped cross section.

The first bar 1601 and the second bar 1602 may face each other in the first direction DR1. The third bar 1603 and the fourth bar 1604 may face each other in the third direction DR3. The first bar 1601 may be disposed between an end of the third bar 1603 and an end of the fourth bar 1604. The second bar 1602 may be disposed between an opposite end of the third bar 1603 and an opposite end of the fourth bar 1604.

The support members 1610, 1620 and 1630 may include one or more first support members 1610 extending from the first bar 1601, one or more second support members 1620 extending from the second bar 1602, and one or more third support members 1630 extending from the third bar 1603. In an embodiment, two first support members 1610 may extend from a side and an opposite side of the first bar 1601 toward the second bar 1602, respectively, for example. In an embodiment, the two first support members 1610 may extend from a side and an opposite side of the first bar 1601 along the first direction DR1. Two second support members 1620 may extend from a side and an opposite side of the second bar 1602 toward the first bar 1601, respectively. In an embodiment, the two second support members 1620 may extend from a side and an opposite side of the second bar 1602 along the second reverse direction, respectively, for example. Two third support members 1630 may extend from a side and an opposite side of the third bar 1603 toward the fourth bar 1604, respectively. In an embodiment, the two third support members 1630 may extend from a side and an opposite side of the third bar 1603 along the third direction DR3, respectively, for example. The two first support members 1610 and the two second support members 1620 may face each other, respectively.

As illustrated in FIG. 5, each of the first support members 1610 may include an extension portion 1611 and a plurality of protrusions 1612. A side of the extension portion 1611 may be connected to the first bar 1601. The extension portion 1611 may extend from the first bar 1601 toward the second bar 1602. The protrusions 1612 (e.g., two protrusions 1612) may be disposed on an opposite side of the extension portion 1611. The protrusions 1612 may be rotatably connected to an opposite side of the extension portion 1611. In an embodiment, each of the protrusions 1612 may rotate about an axis parallel to the first direction DR1, for example. The protrusions 1612 may face each other in the second direction DR2. Each of the protrusions 1612 may have a cylindrical shape. However, the shape of the protrusions 1612 is not limited thereto and may be changed to various shapes.

The second support members 1620 may have the same configuration as the first support members 1610 described above. However, an extension portion of each of the second support members 1620 may extend from the second bar 1602 toward the first bar 1601.

Each of the third support members 1630 may include an extension portion 1631, a protruding portion 1632, and a protrusion 1633. A side of the extension portion 1631 may be connected to the third bar 1603. The extension portion 1631 may extend from the third bar 1603 toward the fourth bar 1604. The protruding portion 1632 may be disposed on an opposite side of the extension portion 1631. The protrusion 1633 may be disposed on a side of the protruding portion 1632. The protrusion 1633 may be rotatably connected to the side of the protruding portion 1632. In an embodiment, the protrusion 1633 may rotate about an axis parallel to the second direction DR2, for example. The protrusion 1633 may have a cylindrical shape. However, the shape of the protrusion 1633 is not limited thereto and may be changed to various shapes.

As illustrated in FIGS. 6 and 7, the first support members 1610, the second support members 1620, and the third support members 1630 may support the mask structure 340.

Each of the first support members 1610 may support the first side 11 of the mask structure 340. In an embodiment, the first side 11 of the mask structure 340 may be placed and supported between the protrusions 1612 of each first support member 1610, for example. Specifically, the first side 11 may be supported as a coupling tip 3a of the first side 11 is placed between the protrusions 1612 of each first support member 1610.

Each of the second support members 1620 may support the second side 22 of the mask structure 340. In an embodiment, the second side 22 of the mask structure 340 may be placed and supported between protrusions of each second support member 1620, for example. Specifically, the second side 22 may be supported as a coupling tip 3a of the second side 22 is placed between the protrusions of each second support member 1620.

Each of the third support members 1630 may support a third side 33 of the mask structure 340. In an embodiment, the third side 33 of the mask structure 340 may be placed and supported on the protrusion 1633 of each third support member 1630, for example. Here, the protrusion 1633 of each third support member 1630 may contact the third side 33.

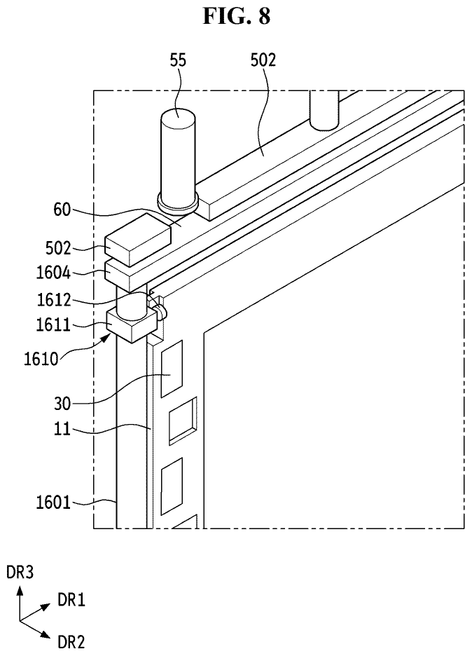

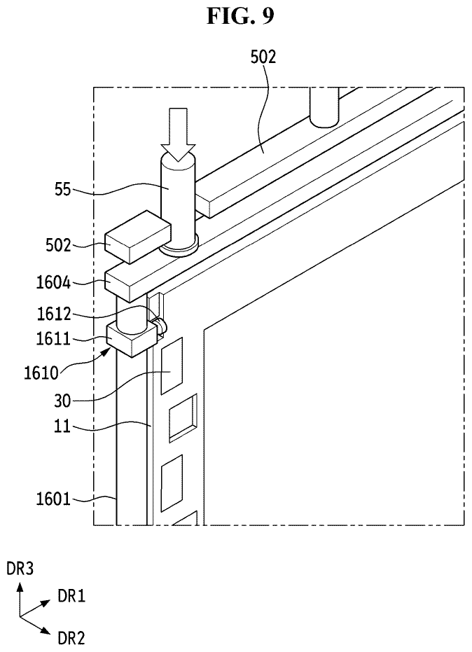

FIGS. 8 and 9 are views for explaining the separation of the first carrier 1600 from the mask structure 340.

The deposition device of the embodiment may further include pushers 55. The pushers 55 may be disposed on the first carrier 1600. In an embodiment, as illustrated in FIG. 8, the pushers 55 may be disposed on the fourth bar 1604 of the first carrier 1600, for example. Specifically, the pushers 55 may face the fourth bar 1604 through openings 60 of the upper track 502. The pushers 55 and the openings 60 of the upper track 502 may be disposed and defined inside the chamber 100.

The pushers 55 may move toward the fourth bar 1604 or in the opposite direction. In an embodiment, the pushers 55 may move along the third reverse direction or the third direction DR3, for example. The pushers 55 may move to a distance of a first stage and a distance of a second stage along the third reverse direction. Here, the distance of the second stage may be greater than the distance of the first stage. Here, when the pushers 55 descend to the distance of the second stage along the third reverse direction, the lower track 501 may also descend along the third reverse direction. In an embodiment, when the pushers 55 descend to the distance of the second stage, the pushers 55 and the lower track 501 may descend together in the same direction, for example.

When the pushers 55 descend to the distance of the second stage along the third reverse direction, they may contact the fourth bar 1604 through the openings 60 of the upper track 502 as illustrated in FIG. 9. At this time, the fourth bar 1604 may be lowered by the pressure of the pushers 55. In other words, as the pushers 55 press the fourth bar 1604 in the third reverse direction, the first carrier 1600 may move in the third reverse direction. Accordingly, the first support members 1610, the second support members 1620, and the third support members 1630 may be moved in the third reverse direction.

Therefore, the protrusions 1612 of each first support member 1610 and the protrusions of each second support member 1620 may be placed to face each other through the separation grooves 3b of the mask structure 340. In other words, the protrusions 1612 of each first support member 1610 and a corresponding coupling tip 3a of the first side 11 of the mask structure 340 do not contact each other, and the protrusions 1612 of each second support member 1620 and a corresponding coupling tip 3a of the second side 22 of the mask structure 340 do not contact each other. In addition, as the first carrier 1600 is lowered along the third reverse direction by the pushers 55 as described above, the third support members 1630 and the mask structure 340 may be separated from each other. In an embodiment, since the protrusions 1612 of the second support members 1620 and the third side 33 of the mask structure 340 are separated from each other, the protrusions 1633 of the third support members 1630 and the third side 33 do not contact each other, for example. Accordingly, the mask structure 340 is no longer supported by the first carrier 1600. Therefore, the mask structure 340 may easily move in the second direction DR2 and the second reverse direction without being interfered with by the first carrier 1600.

A mover 550 may be disposed inside the lower track 501. The mover 550 may have a screw shape. A plurality of permanent magnets may be disposed on an outer circumferential surface of the mover 550. Permanent magnets may also be disposed on the inside of the lower track 501 and on each of facing surfaces of the upper track 502 and the fourth bar 1604 of the first carrier 1600. By the rotation of these permanent magnets and the mover 550, the first carrier 1600 may be moved along the transport track 500 in a magnetic levitation manner. In an embodiment, the movement direction of the first carrier 1600 disposed on the transport track 500 may be controlled according to the rotation direction of the mover 550, for example. Specifically, when the mover 550 rotates clockwise, the first carrier 1600 may move on the transport track 500 along the first direction DR1. When the mover 550 rotates counterclockwise, the first carrier 1600 may move on the transport track 500 along the first reverse direction.

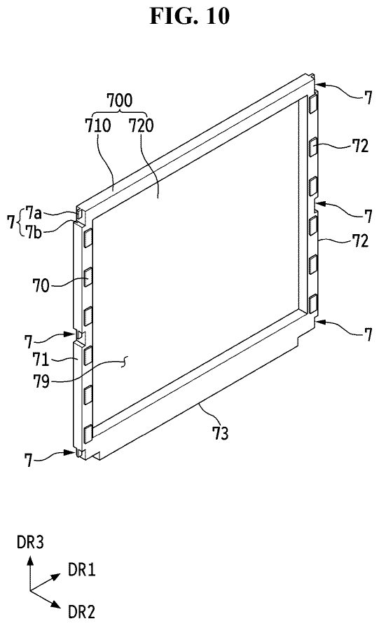

FIG. 10 is a perspective view of the substrate tray 700 of FIG. 1.

As illustrated in FIG. 10, the substrate tray 700 may include a support plate 710 and an electrostatic chuck 720.

The support plate 710 may be shaped like a quadrangular frame with a penetrated central portion. In an embodiment, the support plate 710 may define an opening 79 in the central portion, for example.

The electrostatic chuck 720 may be disposed on the support plate 710. In an embodiment, the electrostatic chuck 720 may be disposed between the support plate 710 and the substrate 50, for example. Here, the electrostatic chuck 720 may cover the opening 79 of the support plate 710. The substrate 50 may be placed on the electrostatic chuck 720. The electrostatic chuck 720 may adsorb the substrate 50 using an electrostatic force.

At least one detachable member 7 may be disposed at edges of the substrate tray 700. In an embodiment, a detachable member 7 may be disposed near each corner of the quadrangular support plate 710, for example. Specifically, the support plate 710 may have six detachable members 7. Here, three of the six detachable members 7 may be disposed at the top, middle and bottom of a first side 71 of the substrate tray 700, respectively, and the remaining three detachable members 7 may be disposed at the top, middle and bottom of a second side 72 of the substrate tray 700, respectively. The first side 71 and the second side 72 of the substrate tray 700 may face each other along the first direction DR1.

Each detachable member 7 may include a coupling tip 7a, and a separation groove 7b may be defined next (adjacent) to the coupling tip 7a in each detachable member 7 in the third direction DR3. The coupling tip 7a may be disposed higher than the separation groove 7b. In an embodiment, in one detachable member 7, the coupling tip 7a may be disposed higher than the separation groove 7b in the third direction DR3, for example. The coupling tip 7a may have a smaller thickness (e.g., size in the second direction DR2) than other parts of the substrate tray 700. In an embodiment, the coupling tip 7a may have a smaller thickness (e.g., size in the second direction DR2) than other parts of the support plate 710, for example. The separation groove 7b may be recessed from the first side 71 of the substrate tray 700 (e.g., the support plate 710) toward the second side 72 or may be recessed from the second side 72 toward the first side 71. In an embodiment, separation grooves 7b defined in different sides and facing each other may be recessed toward each other, for example.

In an embodiment, the detachable members 7 of the substrate tray 700 may have substantially the same structure as that of the detachable members 3 of the frame 300 included in the mask structure 340 described above.

A second carrier 2600 may move along the transport track 500. In an embodiment, the second carrier 2600 may move along the transport track 500 in a magnetic levitation manner, for example. The second carrier 2600 may transport the substrate tray 700. In an embodiment, the first carrier 1600 and the second carrier 2600 may be transported along the same transport track 500 as described above. Therefore, in an embodiment, the deposition device may be simplified, and thus the manufacturing cost of the deposition device may be reduced.

The second carrier 2600 will be described in detail as follows.

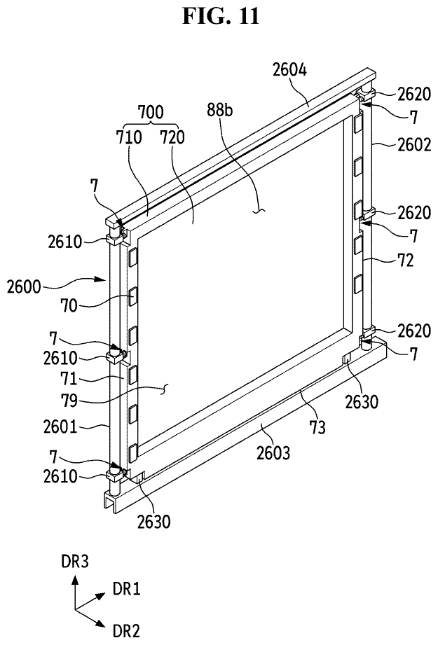

FIG. 11 is a view for explaining the coupling of the substrate tray 700 of FIG. 10 to the second carrier 2600.

The second carrier 2600 may include a plurality of bars 2601, 2602, 2603 and 2604 and a plurality of support members 2610, 2620 and 2630. In an embodiment, the second carrier 2600 may include a first bar 2601, a second bar 2602, a third bar 2603, and a fourth bar 2604 connected to each other, for example. The substrate tray 700 may be placed in an area (e.g., an opening 88b) surrounded and defined by the first bar 2601, the second bar 2602, the third bar 2603, and the fourth bar 2604.

The first bar 2601 and the second bar 2602 may face each other in the first direction DR1. The third bar 2603 and the fourth bar 2604 may face each other in the third direction DR3. The first bar 2601 may be disposed between an end of the third bar 2603 and an end of the fourth bar 2604. The second bar 2602 may be disposed between an opposite end of the third bar 2603 and an opposite end of the fourth bar 2604.

The support members 2610, 2620 and 2630 may include one or more first support members 2610 extending from the first bar 2601, one or more second support members 2620 extending from the second bar 2602, and one or more third support members 2630 extending from the third bar 2603.

The first bar 2601, the second bar 2602, the third bar 2603, the fourth bar 2604, the first support members 2610, the second support members 2620 and the third support members 2630 of the second carrier 2600 are substantially the same as the first bar 1601, the second bar 1602, the third bar 1603, the fourth bar 1604, the first support members 1610, the second support members 1620 and the third support members 1630 of the first carrier 1600 described above, respectively. Therefore, a description of the first bar 2601, the second bar 2602, the third bar 2603, the fourth bar 2604, the first support members 2610, the second support members 2620 and the third support members 2630 of the second carrier 2600 may be found in the above description of the first bar 1601, the second bar 1602, the third bar 1603, the fourth bar 1604, the first support members 1610, the second support members 1620 and the third support members 1630 of the first carrier 1600.

In an embodiment, a method of coupling the substrate tray 700 to the second carrier 2600 may be substantially the same as the above-described method of coupling the mask structure 340 to the first carrier 1600.

In an embodiment, each of the first support members 2610 of the second carrier 2600 may support the first side 71 of the substrate tray 700, for example. In an embodiment, the first side 71 of the substrate tray 700 may be placed and supported between protrusions of each first support member 2610, for example. Specifically, the first side 71 may be supported as a coupling tip 7a of the first side 71 is placed between the protrusions of each first support member 2610.

Each of the second support members 2620 may support the second side 72 of the substrate tray 700. In an embodiment, the second side 72 of the substrate tray 700 may be placed and supported between protrusions of each second support member 2620, for example. Specifically, the second side 72 may be supported as a coupling tip 7a of the second side 72 is placed between the protrusions of each second support member 2620.

Each of the third support members 2630 may support a third side 73 of the substrate tray 700. In an embodiment, the third side 73 of the substrate tray 700 may be placed and supported on a protrusion of each third support member 2630, for example. Here, the protrusion of each third support member 2630 may contact the third side 73.

In an embodiment, a method of separating the substrate tray 700 from the second carrier 2600 may be substantially the same as the above-described method of separating the mask structure 340 from the first carrier 1600.

In an embodiment, when the pushers 55 move along the third reverse direction, they may contact the fourth bar 2604 of the second carrier 2600 through the openings 60 of the upper track 502, for example. At this time, the fourth bar 2604 may be lowered by the pressure of the pushers 55. In other words, as the pushers 55 press the fourth bar 2604 in the third reverse direction, the second carrier 2600 may move in the third reverse direction. Accordingly, the first support members 2610, the second support members 2620, and the third support members 2630 may be moved in the third reverse direction. Therefore, the protrusions of each first support member 2610 and the protrusions of each second support member 2620 may be placed to face each other through the separation grooves 7b of the substrate tray 700. In other words, the protrusions of each first support member 2610 and a corresponding coupling tip 7a of the first side 71 of the substrate tray 700 do not contact each other, and the protrusions of each second support member 2620 and a corresponding coupling tip 7a of the second side 72 of the substrate tray 700 do not contact each other. In addition, as the second carrier 2600 is lowered along the third reverse direction by the pushers 55 as described above, the third support members 2630 and the substrate tray 700 may be separated from each other. In an embodiment, since the protrusions of the second support members 2620 and the third side 73 of the substrate tray 700 are separated from each other, the protrusions of the third support members 2630 and the third side 73 do not contact each other, for example. Accordingly, the substrate tray 700 is no longer supported by the second carrier 2600. Therefore, the substrate tray 700 may easily move in the second direction DR2 and the second reverse direction without being interfered with by the second carrier 2600.

A deposition method of the deposition device in the embodiment configured as described above will be described in detail as follows.

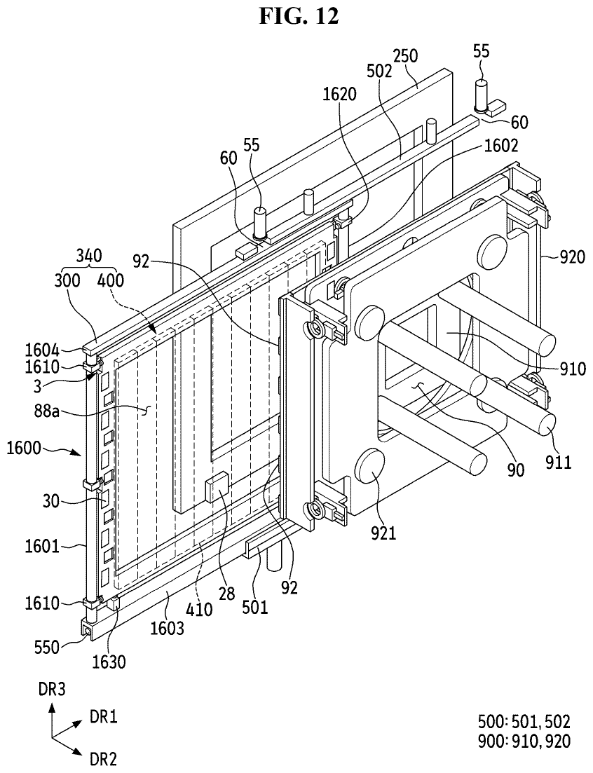

FIGS. 12, 13, and 14 are views for explaining an embodiment of a deposition method of the deposition device.

First, the deposition source 200, the stage 250, the first driving mechanism 910, and the second driving mechanism 920 may be disposed inside the chamber 100. At this time, the magnet plate 800 may be attached to the first driving mechanism 910. In addition, the first driving mechanism 910 and the second driving mechanism 920 may be disposed between the transport track 500 and the second inner wall 102 of the chamber 100 so as not to overlap the transport track 500.

Next, as illustrated in FIG. 12, the first carrier 1600 loaded with the mask structure 340 may be loaded into the chamber 100 along the transport track 500. In an embodiment, the first carrier 1600 loaded with the mask structure 340 may be loaded (or placed) into the chamber 100 through the first gate G1 of the chamber 100 along the transport track 500, for example. In an embodiment, the first carrier 1600 may be placed inside the chamber 100 such that the mask structure 340 is aligned with the stage 250 between the stage 250 and the driving mechanism 900, for example.

Next, the pushers 55 may descend to the distance of the first stage along the third reverse direction to contact the first carrier 1600. The first carrier 1600 may be lowered along the third reverse direction by the pressure of the pushers 55. At this time, since the lower track 501 remains as it is without being lowered, a gap between the first carrier 1600 and the lower track 501 may be reduced. Accordingly, the first carrier 1600 may be stably placed on the lower track 501 inside the chamber 100. Here, when the pushers 55 descend to the distance of the first stage, the descending distance is short. Therefore, even when the first carrier 1600 is lowered by the pressure of the pushers 55, the mask structure 340 accommodated in the first carrier 1600 may be kept supported by the support members 1610, 1620 and 1630 of the first carrier 1600.

Next, the second driving mechanism 920 may recognize the position of the mask structure 340 and adjust an attachment position between the second driving mechanism 920 and the mask structure 340. In an embodiment, the position of the driving mechanism 900 including the second driving mechanism 920 may be adjusted for alignment between the electro-permanent magnets 92 of the second driving mechanism 920 and the grooves 30 of the mask structure 340, for example.

Next, the driving mechanism 900 may move toward the first carrier 1600. At this time, as the electro-permanent magnets 92 of the second driving mechanism 920 and the frame 300 of the mask structure 340 contact each other, the mask structure 340 may be attached to the second driving mechanism 920. In an embodiment, the electro-permanent magnets 92 of the second driving mechanism 920 may be inserted into the grooves 30 of the frame 300, and the frame 300 may be attached to the second driving mechanism 920 by a magnetic force from the electro-permanent magnets 92, for example. In other words, the frame 300 of the mask structure 340 and the mask structure 340 in the first carrier 1600 may be attached to the second driving mechanism 920.

Next, while the mask structure 340 is attached to the second driving mechanism 920, the pushers 55 may further descend to the distance of the second stage, and the lower track 501 may also descend along the third reverse direction at the same time as the pushers 55. In other words, the pushers 55 and the lower track 501 may simultaneously descend along the third reverse direction. Accordingly, the first carrier 1600 and the lower track 501 may descend along the third reverse direction. At this time, the gap between the first carrier 1600 and the lower track 501 may be substantially equal to the gap between the first carrier 1600 and the lower track 501 when the pushers 55 descend to the distance of the first stage described above. Accordingly, a constraining force of the support members 1610, 1620 and 1630 of the first carrier 1600 applied to the mask structure 340 may be removed. Therefore, the mask structure 340 may be maintained in a state where it may move in the second direction DR2 and the second reverse direction from the first carrier 1600.

Next, the driving mechanism 900 may move further along the second reverse direction. In other words, the driving mechanism 900 may move toward the stage 250. Accordingly, the mask structure 340 attached to the second driving mechanism 920 may be separated from the first carrier 1600 in the second reverse direction and moved in the second reverse direction along with the second driving mechanism 920 to leave the transport track 500. Next, the driving mechanism 900 to which the mask structure 340 is attached may move further in the second reverse direction toward the stage 250 to place the mask structure 340 on the stage 250. In an embodiment, the mask structure 340 may be placed on the supports 28 of the stage 250, for example. At this time, the electro-permanent magnets of the stage 250 and the frame 300 of the mask structure 340 may be attached to each other. When the mask structure 340 is placed on the stage 250, the second driving mechanism 920 and the mask structure 340 may be separated from each other. In an embodiment, the mask structure 340 may be separated from the second driving mechanism 920 as the magnetic force of the electro-permanent magnets 92 of the second driving mechanism 920 is released, for example.

In an embodiment, a distance that the driving mechanism 900 (e.g., the second driving mechanism 920) moves in the process of placing the mask structure 340 on the stage 250 may be smaller than a width W of the transport track 500. In an embodiment, the position of the second driving mechanism 920 at a time when the mask structure 340 (e.g., the mask structure 340 placed in the first carrier 1600) is attached to the second driving mechanism 920 may be defined as a first position, and the position of the second driving mechanism 920 at a time when the mask structure 340 and the stage 250 contact each other due to the second driving mechanism 920 moving from the first position toward the stage 250 (or at a time when the mask structure 340 and the second driving mechanism 920 in contact with each other are separated after the mask structure 340 is placed and aligned on the stage 250) may be defined as a second position, for example. In this case, the movement distance of the second driving mechanism 920 from the first position to the second position may be smaller than the width W of the transport track 500. In other words, the distance that the driving mechanism (e.g., the second driving mechanism 920) moves to transfer the mask structure 340 from the first carrier 1600 to the stage 250 may be smaller than the width W of the transport track 500. Here, the width W of the transport track 500 may be defined as a width W of the lower track 501 in the second direction DR2 as in the example illustrated in FIG. 5. In this case, the movement distance of the second driving mechanism 920 from the first position to the second position may be smaller than the width W described above. The width W of the transport track 500 may also be defined as a width of the upper track 502 (e.g., a width of the upper track 502 in the second direction DR2), for example. In this case, the movement distance of the second driving mechanism 920 from the first position to the second position may be smaller than the width of the upper track 502 described above. Therefore, the distance that the driving mechanism (e.g., the second driving mechanism 920) moves to transfer the mask structure 340 from the first carrier 1600 to the stage 250 may be considerably short. Accordingly, the time desired to transfer the mask structure 340 of the first carrier 1600 to the stage 250 may be short, thereby minimizing misalignment (e.g., alignment defect) of the mask structure 340 in the process of moving the mask structure 340.

Next, the driving mechanism 900 may be moved in the second direction DR2. In an embodiment, the driving mechanism 900 may pass through the opening 88a of the first carrier 1600 along the second direction DR2, for example. Then, the driving mechanism 900 may be placed between the transport track 500 and the second inner wall 102 of the first chamber 100.

Next, the pushers 55 may be raised and moved to the original position. Accordingly, the first carrier 1600 (e.g., the empty first carrier 1600) which has transported the mask structure 340 may be raised and moved to the original position. Then, the first carrier 1600 (e.g., the empty first carrier) may be unloaded from the chamber 100 through the second gate G2 of the chamber 100 along the transport track 500.

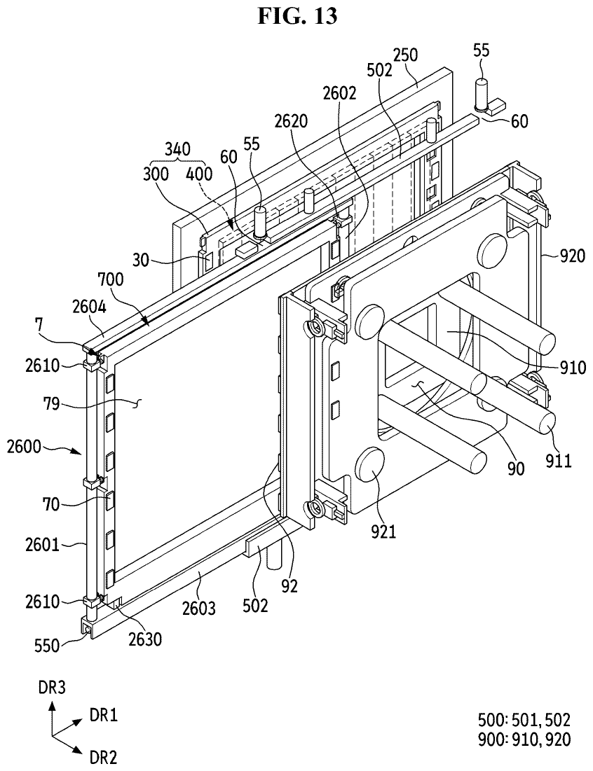

Next, as illustrated in FIG. 13, the second carrier 2600 loaded with the substrate tray 700 (e.g., the substrate tray 700 on which the substrate 50 is placed) may be loaded into the chamber 100 along the transport track 500. In an embodiment, the second carrier 2600 loaded with the substrate tray 700 may be loaded (or placed) into the chamber 100 through the first gate G1 of the chamber 100 along the transport track 500, for example. As a predetermined example, the second carrier 2600 may be placed inside the chamber 100 such that the substrate tray 700 is aligned with the mask structure 340 between the mask structure 340 and the driving mechanism 900.

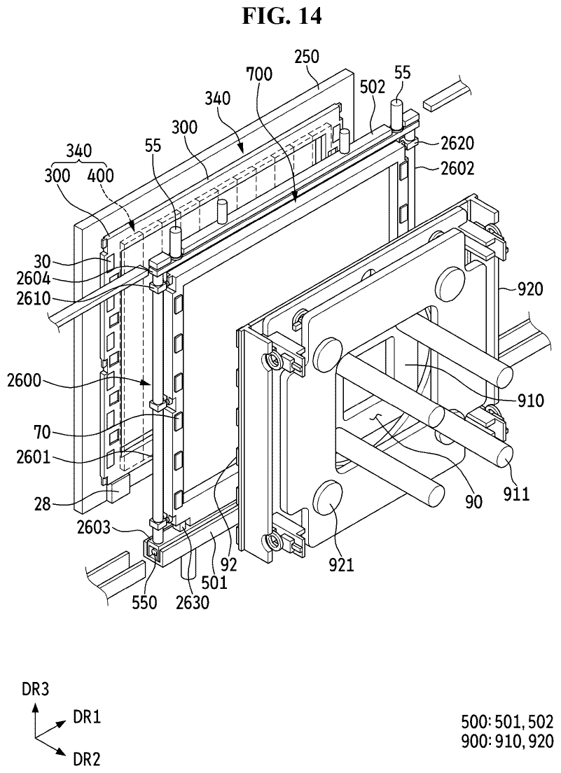

Next, as illustrated in FIG. 14, the pushers 55 may descend to the distance of the first stage along the third reverse direction to contact the second carrier 2600. The second carrier 2600 may be lowered along the third reverse direction by the pressure of the pushers 55. At this time, since the lower track 501 remains as it is without being lowered, a gap between the second carrier 2600 and the lower track 501 may be reduced. Accordingly, the second carrier 2600 may be stably placed on the lower track 501 inside the chamber 100. Here, when the pushers 55 descend to the distance of the first stage, the descending distance is short. Therefore, even when the second carrier 2600 is lowered by the pressure of the pushers 55, the substrate tray 700 accommodated in the second carrier 2600 may be kept supported by the support members 2610, 2620 and 2630 of the second carrier 2600.

Next, the second driving mechanism 920 may recognize the position of the substrate tray 700 and adjust an attachment position between the second driving mechanism 920 and the substrate tray 720. In an embodiment, the position of the driving mechanism 900 including the second driving mechanism 920 may be adjusted for alignment between the electro-permanent magnets 92 of the second driving mechanism 920 and the magnetic objects 70 of the substrate tray 700, for example.

Next, the driving mechanism 900 may move toward the second carrier 2600. At this time, as the electro-permanent magnets 92 of the second driving mechanism 920 and the magnetic objects 70 of the substrate tray 700 contact each other, the substrate tray 700 may be attached to the second driving mechanism 920. In an embodiment, the substrate tray 700 may be attached to the second driving mechanism 920 by a magnetic force from the electro-permanent magnets 92, for example.

Next, while the substrate tray 700 is attached to the second driving mechanism 920, the pushers 55 may further descend to the distance of the second stage, and the lower track 501 may also descend along the third reverse direction at the same time as the pushers 55. In other words, the pushers 55 and the lower track 501 may simultaneously descend along the third reverse direction. Accordingly, the second carrier 2600 and the lower track 501 may descend along the third reverse direction. At this time, the gap between the second carrier 2600 and the lower track 501 may be substantially equal to the gap between the second carrier 2600 and the lower track 501 when the pushers 55 descend to the distance of the first stage described above. Accordingly, a constraining force of the support members 2610, 2620 and 2630 of the second carrier 2600 applied to the substrate tray 700 may be removed. Therefore, the substrate tray 700 may be maintained in a state where it may move in the second direction DR2 and the second reverse direction from the second carrier 2600.

Next, the driving mechanism 900 may move further along the second reverse direction. In other words, the driving mechanism 900 may move toward the mask structure 340 on the stage 250. Accordingly, the substrate tray 700 attached to the second driving mechanism 920 may be separated from the second carrier 2600 in the second reverse direction and moved in the second reverse direction along with the second driving mechanism 920 to leave the transport track 500. Next, the driving mechanism 900 to which the substrate tray 700 is attached may move further in the second reverse direction toward the mask structure 340 on the stage 250 to place the substrate tray 700 on the mask structure 340.

Next, the first driving mechanism 910 may be moved further along the second reverse direction toward the substrate tray 700. Accordingly, the magnet plate 800 attached to the first driving mechanism 910 may become close to the substrate tray 700 or may contact the substrate tray 700. Then, the mask structure 340 may be attracted toward the magnets 820 of the magnet plate 800 by a magnetic force from the magnet plate 800. Accordingly, the adhesion between the substrate 50 on the substrate tray 700 and the mask structure 340 may be improved.

Next, a deposition material from the deposition source 200 may be deposited on the substrate 50 through the pattern holes of the mask structure 340. In an embodiment, a deposition process may be performed on the substrate 50, for example.

When the deposition process on the substrate 50 is completed, the first driving mechanism 910 to which the magnet plate 800 is attached may move along the second direction DR2, thereby weakening the adhesion between the mask structure 340 and the substrate 50.

Next, the driving mechanism 900 may be moved in the second direction DR2. At this time, the substrate tray 700 (e.g., the substrate tray 700 on which the substrate 50 which has gone through the deposition process is placed) attached to the second driving mechanism 920 may also be moved in the second direction DR2. The substrate tray 700 attached to the second driving mechanism 920 may be recoupled (or reloaded) to the second carrier 2600 (e.g., the empty second carrier 2600). In an embodiment, the substrate tray 700 may be placed in the opening 88b of the second carrier 2600 by the movement of the driving mechanism 900, for example. At this time, as the pushers 55 pressing the second carrier 2600 ascend along the third direction DR3 and return to the original position, the support members 2610, 2620 and 2630 of the second carrier 2600 and the substrate tray 700 may contact each other again. Accordingly, the substrate tray 700 (e.g., the substrate tray 700 on which the substrate 50 which has gone through the deposition process is placed) may be recoupled (or reloaded) to the second carrier 2600. After the substrate tray 700 is recoupled to the second carrier 2600, the second driving mechanism 920 and the substrate tray 700 may be separated from each other. In an embodiment, the magnetic force of the electro-permanent magnets 92 of the second driving mechanism 920 may be released, thereby separating the second driving mechanism 920 and the substrate tray 700 from each other, for example.

Next, the driving mechanism 900 may be moved further in the second direction DR2. Accordingly, the driving mechanism 900 may be placed between the transport track 500 and the second inner wall 102 of the first chamber 100.

Next, the second carrier 2600 loaded with the substrate tray 700 (e.g., the substrate tray 700 on which the substrate 50 which has gone through the deposition process is placed) may be unloaded from the chamber 100 through the second gate G2 of the chamber 100 along the transport track 500.

When the first driving mechanism 910 is moved during the above deposition process, it may be moved together with the second driving mechanism 920. Similarly, when the second driving mechanism 920 is moved during the deposition process, it may be moved together with the first driving mechanism 910. In an embodiment, when the first driving mechanism 910 is disposed on a movement path along which the second driving mechanism 920 is moved, the second driving mechanism 920 and the first driving mechanism 910 may move together, for example. At this time, the first driving mechanism 910 may be moved together with the second driving mechanism 920 while being disposed within the second driving mechanism 920. In an embodiment, as illustrated in FIG. 1, the second driving mechanism 920 may have a cross section (e.g., a “]”-shaped cross section) surrounding the first driving mechanism 910, for example. Therefore, the first driving mechanism 910 may be moved together with the second driving mechanism 920 while being disposed within the second driving mechanism 920 and surrounded by the second driving mechanism 920.

In an embodiment, an area (hereinafter, also referred to as a “first area”) where the mask structure 340 in the first carrier 1600 is attached to the second driving mechanism 920 within the chamber 100 may be the same as or may partially overlap an area (hereinafter, also referred to as a “second area”) where the substrate tray 700 in the second carrier 2600 is attached to the second driving mechanism 920 within the chamber 100. In other words, the first area and the second area may completely overlap each other or at least partially overlap each other.

In an embodiment, the first area may correspond to the opening 88a of the first carrier 1600 (e.g., the first carrier 1600 loaded with the mask structure 340) loaded into the chamber 100, and the second area may correspond to the opening 88b of the second carrier 2600 (e.g., the second carrier 2600 loaded with the substrate tray 700) loaded into the chamber 100. In other words, when the second driving mechanism 920 holds (or grips) the mask structure 340 of the first carrier 1600 or the substrate tray 700 of the second carrier 2600 within the chamber 100, it may hold the mask structure 340 or the substrate tray 700 in the same area of the chamber 100. Therefore, in the process of sequentially gripping a plurality of different structures (e.g., the mask structure 340 and the substrate tray 700), unnecessary movement of the second driving mechanism 920 may be reduced, thereby minimizing the tact time of the deposition device.

According to a deposition device and method of deposition for a display device in an embodiment, the manufacturing cost, tact time, and misalignment of the deposition device may be minimized.

The display device in the embodiment may be applied to various electronic devices. The electronic device in an embodiment includes the display device described above and may further include modules or devices having additional functions in addition to the display device.

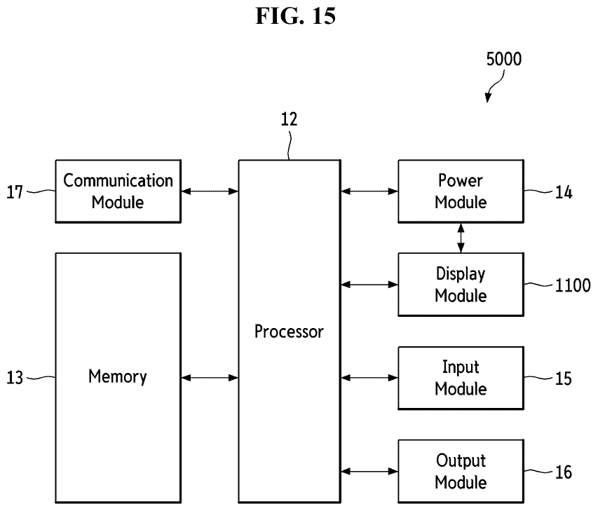

FIG. 15 is a block diagram of an embodiment of an electronic device. Referring to FIG. 15, the electronic device 5000 in an embodiment may include a display module (e.g., a display device) 1100, a processor 12, a memory 13, and a power module 14. The electronic device 5000 may further include an input module 15, a non-image output module (also referred to as an output module) 16 and/or a communication module 17.

The electronic device 5000 may output various information in the form of images through the display module 1100. When the processor 12 executes an application stored in the memory 13, image information provided by the application may be provided to the user through the display module 1100. The power module 15 may include a power supply module such as a power adapter or a battery device, and a power conversion module that converts the power supplied by the power supply module to generate power desired for the operation of the electronic device 5000. The input module 14 may provide input information to the processor 12 and/or the display module 1100. The non-image output module 16 may receive information other than images transmitted from the processor 12, such as sound, haptics, and light, and provide the information to the user. The communication module 17 is a module that is responsible for transmitting and receiving information between the electronic device 5000 and an external device, and may include a receiving unit and a transmitting unit.

At least one of the components of the electronic device 5000 described above may be included in the display device in the embodiments described above. In addition, some of the individual modules functionally included in one module may be included in the display device, and others may be provided separately from the display device. In an embodiment, the display device includes a display module 1100, and the processor 12, memory 13, and power module 14 may be provided in the form of other devices within the electronic device 11 other than the display device, for example.

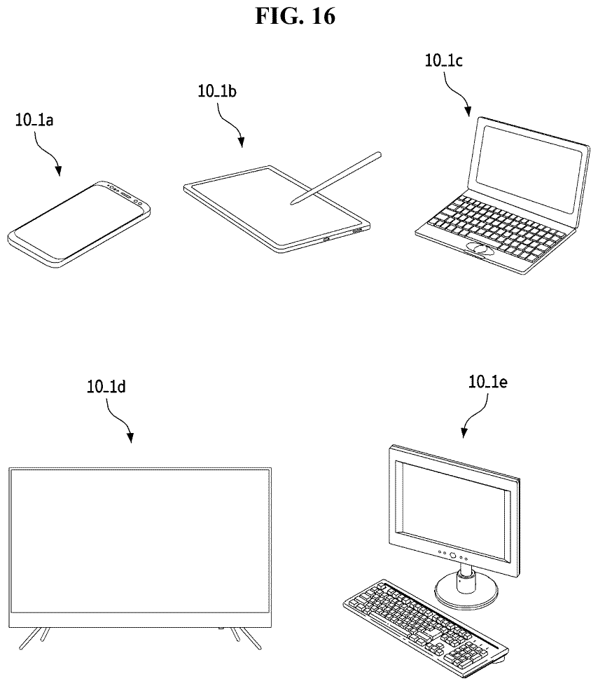

FIGS. 16, 17, and 18 are schematic diagrams of electronic devices according to various embodiments. FIGS. 16 to 18 illustrate embodiments of various electronic devices to which the display device in the embodiments is applied.

FIG. 16 illustrates a smartphone 10_1a, a tablet personal computer (“PC”) 10_1b, a laptop 10_1c, a television (“TV”) 10_1d, and a desk monitor 10_1e as embodiments of electronic devices.

In addition to the display module 1100, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1a, and may additionally include communication modules in some cases.

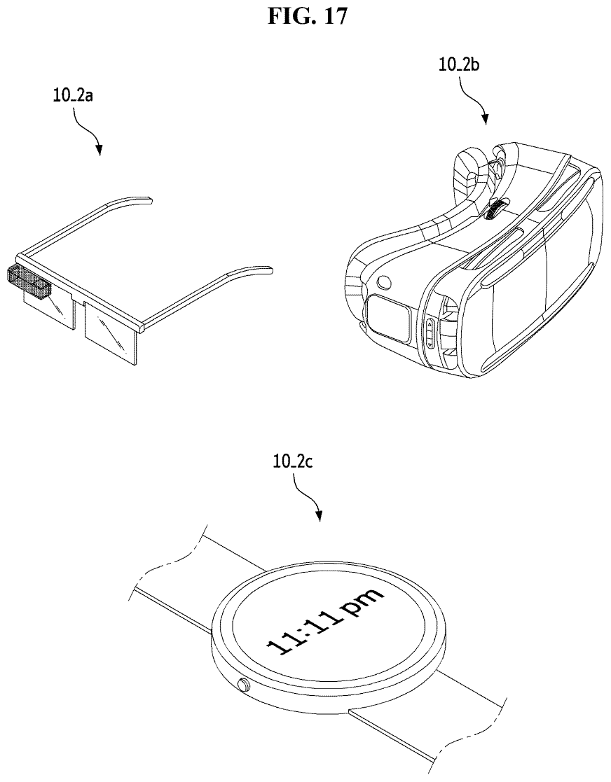

FIG. 17 shows an embodiment of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

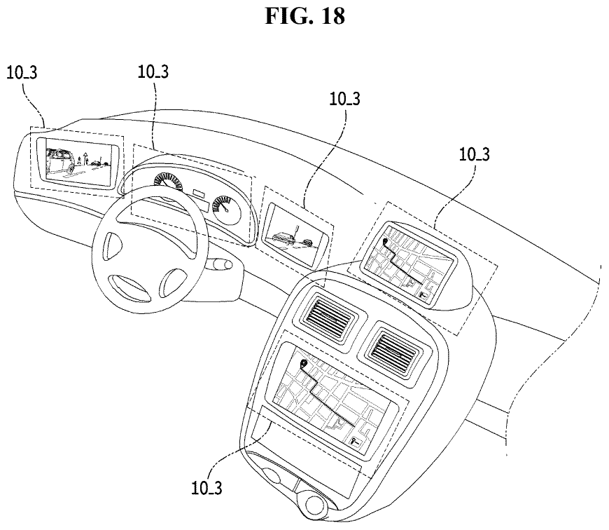

The smart watch 10_2c includes a biometric sensor as an input device, and may provide biometric information recognized by the biometric sensor to the user through the display module. FIG. 18 illustrates a case where an electronic device including a display module is applied to a vehicle. In an embodiment, the electronic device 10_3 may be applied to a dashboard, center fascia, etc. of a vehicle, or may be applied to a center information display (“CID”) placed on a dashboard of a vehicle, or a room mirror display replacing a side mirror, for example.

It will be able to be understood by one of ordinary skill in the art to which the disclosure belongs that the disclosure may be implemented in other predetermined forms without changing the technical spirit or essential features of the disclosure. Therefore, it is to be understood that the embodiments described above are illustrative rather than being restrictive in all features. It is to be understood that the scope of the disclosure are defined by the claims rather than the detailed description described above and all modifications and alterations derived from the claims and their equivalents fall within the scope of the disclosure.

What is claimed is:

1. A deposition device for a display device, the deposition device comprising:
a chamber including:
a first gate; and
a second gate;
a deposition source in the chamber;
a stage on the deposition source;
a mask structure on the stage;
a substrate tray on the mask structure;
a magnet plate on the substrate tray;
a transport track passing through the first gate and the second gate and disposed inside the chamber and outside the chamber;
a first carrier which transports the mask structure along the transport track; and
a second carrier which transports the substrate tray along the transport track.

2. The deposition device of claim 1, further comprising a first driving mechanism which moves the magnet plate.

3. The deposition device of claim 1, further comprising a second driving mechanism which moves the mask structure and the substrate tray.

4. The deposition device of claim 3, wherein an area where the mask structure in the first carrier is attached to the second driving mechanism within the chamber is identical to an area where the substrate tray in the second carrier is attached to the second driving mechanism within the chamber.

5. The deposition device of claim 3, wherein a distance that the second driving mechanism transfers the mask structure from the first carrier to the stage is smaller than a width of the transport track.

6. The deposition device of claim 5, wherein the width of the transport track is a width of a lower track of the transport track.

7. The deposition device of claim 6, wherein the width of the transport track is a width of an upper track of the transport track.

8. The deposition device of claim 1, wherein the transport track comprises:
a lower track; and
an upper track on the lower track.

9. The deposition device of claim 8, wherein the first carrier and the second carrier are disposed between the lower track and the upper track.

10. The deposition device of claim 9, wherein the first carrier comprises:
a first bar;
a second bar facing the first bar;
a third bar disposed on the lower track;
a fourth bar disposed under the upper track and facing the third bar;
a first support member extending from the first bar toward the second bar;
a second support member extending from the second bar toward the first bar; and
a third support member extending from the third bar toward the fourth bar,
wherein an opening surrounded by the first bar, the second bar, the third bar, and
the fourth bar is defined in the first carrier.

11. The deposition device of claim 10, wherein the first support member comprises:
an extension portion extending from the first bar; and
a protrusion rotatably connected to a side of the extension portion.

12. The deposition device of claim 11, wherein the third support member comprises:
an extension portion extending from the third bar;
a protruding portion disposed on a side of the extension portion; and
a protrusion rotatably disposed on a side of the protruding portion.

13. The deposition device of claim 10, further comprising a pusher facing the fourth bar through an opening of the upper track and movable toward the fourth bar.

14. The deposition device of claim 10, wherein the mask structure comprises a detachable member disposed next to each of the first support member and the second support member.

15. The deposition device of claim 14, wherein the detachable member comprises a coupling tip, and
a separation groove is defined next to the coupling tip in the detachable member.

16. The deposition device of claim 15, wherein the coupling tip is disposed higher than the separation groove in the first carrier.

17. The deposition device of claim 15, wherein the coupling tip has a smaller thickness than other parts of the second carrier.

18. The deposition device of claim 15, wherein the separation groove is recessed from a side of the first carrier toward an opposite side of the first carrier.

19. A deposition method for a display device, the deposition method comprising:
placing a deposition source, a stage, a first driving mechanism, a magnet plate attached to the first driving mechanism, a second driving mechanism, a pusher, and a transport track between a first inner wall of a chamber and a second inner wall of the chamber;
loading a first carrier loaded with a mask structure, which comprises a mask, into the chamber by moving the first carrier along the transport track;
attaching the second driving mechanism and the mask structure in the first carrier to each other;
releasing a constraining force of support members of the first carrier applied to the mask structure by lowering the first carrier and the support members of the first carrier by pressing the first carrier with the pusher while lowering a lower track of the transport track;
separating the mask structure from the first carrier by moving the second driving mechanism to which the mask structure is attached;
placing the mask structure on the stage by moving the second driving mechanism toward the stage;
separating the second driving mechanism and the mask structure;
placing the second driving mechanism between the transport track and the second inner wall of the chamber;
moving the pusher to an original position;
unloading the first carrier from the chamber by moving the first carrier along the transport track;
loading a second carrier loaded with a substrate tray, which comprises a substrate, into the chamber by moving the second carrier along the transport track;
attaching the second driving mechanism and the substrate tray in the second carrier to each other;
releasing a constraining force of support members of the second carrier applied to the substrate tray by lowering the second carrier and the support members of the second carrier by pressing the second carrier with the pusher while lowering the lower track of the transport track;
separating the substrate tray from the second carrier by moving the second driving mechanism to which the substrate tray is attached;
placing the substrate tray on the mask structure by moving the second driving mechanism toward the mask structure on the stage;
placing the magnet plate on the substrate tray by moving the first driving mechanism toward the substrate tray; and
depositing a deposition material from the deposition source on the substrate through the mask of the mask structure.

20. An electronic device comprising:
a display device;
wherein a deposition device which deposits a deposition material to a substrate of the display device includes:
a chamber;
a deposition source in the chamber;
a stage on the deposition source;
a mask structure on the stage;
a substrate tray on the mask structure;
a magnet plate on the substrate tray;
a transport track passing through a first gate of the chamber and a second gate of the chamber and disposed inside the chamber and outside the chamber;
a first carrier which transports the mask structure along the transport track; and
a second carrier which transports the substrate tray along the transport track.
